(19) United States
(12) Patent Application Publication
(10) Pub. No.: US 2013/0213932 A1
(43) Pub. Date: Aug. 22, 2013

(54) PATTERN FORMATION METHOD AND METAL STRUCTURE FORMATION METHOD

(71) Applicant: FUJIFILM Corporation, (US)

(72) Inventor: Tomokazu UMEZAWA, Minamiashigara-shi (JP)

(73) Assignee: FUJIFILM Corporation, Tokyo (JP)

(21) Appl. No.: 13/851,607

(22) Filed: Mar. 27, 2013

Related U.S. Application Data
(63) Continuation of application No. PCT/JP2011/005383, filed on Sep. 26, 2011.

(30) Foreign Application Priority Data
Sep. 29, 2010 (JP) 2010-218305

(51) Int. Cl. G03F 7/20

(52) U.S. Cl. CPC G03F 7/20
USPC 216/49; 430/348

(57) ABSTRACT

A resist layer made of oxonol-based dye, and the OD value of which is greater than or equal to 1.0 and less than or equal to 1.6 with respect to light having the wavelength of 580 nm, is formed on a substrate. The formed resist layer is scanned with a laser beam at a scan speed of higher than or equal to 3 m/s and lower than or equal to 10 m/s. A ring-shaped pattern is formed by developing the resist layer scanned with the laser beam using a developer containing alcohol as a main component.

### BACKGROUND OF THE INVENTION

1. Field of the Invention

The present invention relates to a pattern formation method for forming ring-shaped patterns by thermal lithography. Further, the present invention relates to a metal structure formation method for forming a ring-shaped metal structure (hereinafter, referred to as a metal ring) using a pattern formed by such a pattern formation method.

2. Description of the Related Art

Recently, there is a growing interest in an artificial material that is called as meta-material. The meta-material has a different behavior from behaviors of natural materials, and for example, it has a negative refractive index with respect to electromagnetic waves including light. Such a meta-material is producible by regularly and three-dimensionally arranging metal rings smaller than the wavelength of target electromagnetic waves.

Japanese Unexamined Patent Publication No. 2009-013453 (Patent Document 1) proposes a method for forming metal rings constituting the meta-material by applying metal coating to the sides of beads compressed by two substrates.

### SUMMARY OF THE INVENTION

Meanwhile, it is necessary to form metal rings the size of which is in the order of several hundreds nm or less to produce a meta-material that has the aforementioned characteristic properties with respect to electromagnetic waves having short wavelengths, such as visible light.

However, in the metal ring formation method disclosed in Patent Document 1, metal rings are formed by applying metal coating to the sides of beads the size of which is a few micrometers or more. Therefore, the minimum size of metal rings formable as a result is only a few micrometer. The meta-material produced by these rings exhibits the aforementioned characteristic properties as a meta-material with respect to microwaves or electromagnetic waves the wavelength of which is longer than that of the microwaves. However, the meta-material does not exhibit properties as a meta-material with respect to visible light, which has a shorter wavelength.

In view of the foregoing circumstances, it is an object of the present invention to provide a pattern formation method that can form ring-shaped patterns of the order of several hundreds rim or less, and a metal structure formation method for forming a ring-shaped metal structure using the pattern formed by such a pattern formation method.

A pattern formation method of the present invention is a pattern formation method for forming a ring-shaped pattern by thermal lithography, the method comprising the steps of:

forming, on a substrate, a resist layer made of oxonol-based dye, and the OD value of which is greater than or equal to 1.0 and less than or equal to 1.6 with respect to light having the wavelength of 580 rim;

scanning the formed resist layer with a laser beam at a scan speed of higher than or equal to 3 m/s and lower than or equal to 10 m/s; and

developing the resist layer scanned with the laser beam using a developer containing alcohol as a main component.

Here, the term “main component” is defined as a component the content of which is 50 mol % or higher. Further, the developer may be diluted with a solvent, such as water.

In the aforementioned method, a protective layer the thickness of which is less than or equal to 10 rim may be further formed on the resist layer, and the resist layer on which the protective layer has been formed may be scanned with the laser beam.

Further, the scan speed may be higher than or equal to 3.8 m/s and lower than or equal to 9.2 m/s.

Further, the alcohol may be methanol or ethanol.

A metal structure formation method of the present invention is a metal structure formation method for forming a ring-shaped metal structure, the method comprising the steps of:

forming a metal layer on a substrate;

forming, on the formed metal layer, a resist layer made of oxonol-based dye, and the OD value of which is greater than or equal to 1.0 and less than or equal to 1.6 with respect to light having the wavelength of 580 nm;

scanning the formed resist layer with a laser beam at a scan speed of higher than or equal to 3 m/s and lower than or equal to 10 m/s;

forming a ring-shaped pattern on the metal layer by developing the resist layer scanned with the laser beam using a developer containing alcohol as a main component; and

etching the metal layer by using the formed ring-shaped pattern as a mask.

According to the pattern formation method of the present invention, a resist layer made of oxonol-based dye, and the OD value of which is greater than or equal to 1.0 and less than or equal to 1.6 with respect to light having the wavelength of 580 nm, is formed on a substrate, and the formed resist layer is scanned with a laser beam at a scan speed of higher than or equal to 3 m/s and lower than or equal to 10 m/s, and the resist layer scanned with the laser beam is developed by using a developer containing alcohol as a main component. Accordingly, it is possible to form a ring-shaped pattern of the order of several hundreds nm.

In the aforementioned method, when a protective layer the thickness of which is less than or equal to 10 nm is further formed on the formed resist layer, and the resist layer on which the protective layer has been formed is scanned with a laser beam, it is possible to form the ring-shaped pattern in more excellent shape.

According to the metal structure formation method of the present invention, a metal layer is formed on a substrate, and a resist layer made of oxonol-based dye, and the OD value of which is greater than or equal to 1.0 and less than or equal to 1.6 with respect to light having the wavelength of 580 nm, is formed on the formed metal layer, and the formed resist layer is scanned with a laser beam at a scan speed of higher than or equal to 3 m/s and lower than or equal to 10 m/s, and a ring-shaped pattern is formed on the metal layer by developing the resist layer scanned with the laser beam by using a developer containing alcohol as a main component, and the metal layer is etched by using the formed ring-shaped pattern as a mask. Accordingly, it is possible to form a ring-shaped metal structure of the order of several hundreds nm.

### BRIEF DESCRIPTION OF THE DRAWINGS

FIG. 1 is a flow chart illustrating a pattern formation method of the present invention;

FIG. 2 is a diagram illustrating the processing state of a pattern formed in Example 1;

FIG. 3 is a diagram illustrating the processing state of a pattern formed in Example 2;

FIG. 4 is a diagram illustrating the processing state of a pattern formed in Example 3;

FIG. 5 is a diagram illustrating the processing state of a pattern formed in Example 4;

FIG. 6 is a diagram illustrating the processing state of a pattern formed in Comparison Example 1; and

FIG. 7 is a flow chart illustrating a metal structure formation method of the present invention.

### DESCRIPTION OF THE PREFERRED EMBODIMENTS

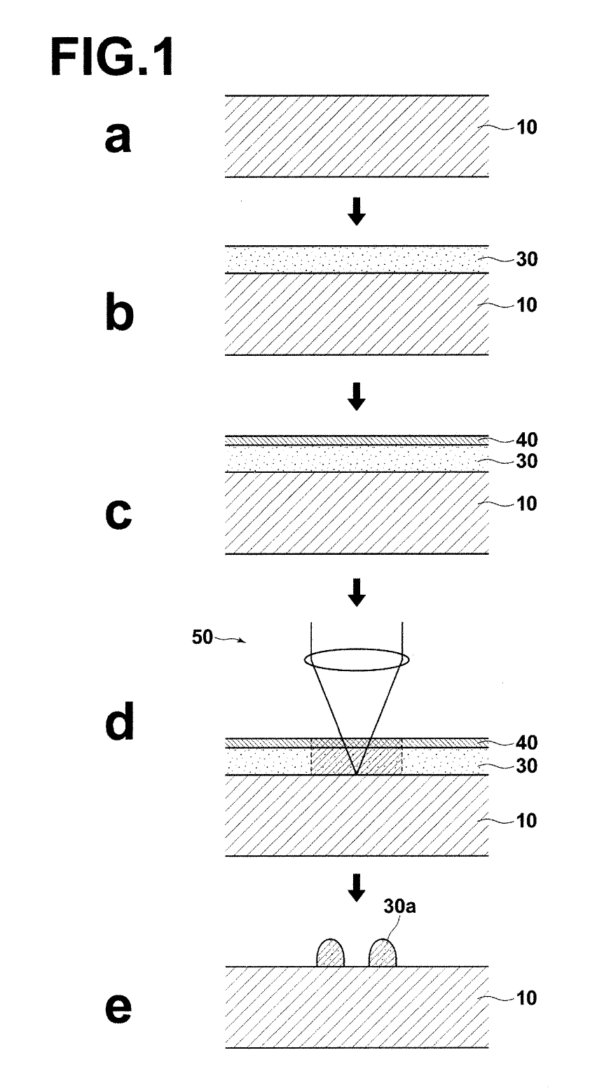

Hereinafter, embodiments of a pattern formation method of the present invention will be described with reference to drawings. FIG. 1 is a diagram illustrating steps of forming a pattern according to the present invention. The pattern formation method of the present invention forms a ring-shaped pattern by thermal lithography, and includes a resist layer formation step, a protective layer formation step, a laser beam scan step, and a development step. The resist layer formation step forms a resist layer 30 on a substrate 10. The protective layer formation step forms a protective layer 40 on the resist layer 30. The laser beam scan step scans the resist layer 30 with a laser beam. The development step develops the resist layer 30 that has been scanned with the laser beam using a developer. Next, each step will be described in detail.

### [Resist Layer Formation Step]

First, as illustrated in Sections a and b of FIG. 1, a flat substrate 10 is prepared, and a resist layer 30 made of oxonol-based dye is formed on the substrate 10. For example, a silicon substrate is used as the substrate 10.

The resist layer 30 is formed by preparing a coating solution in which oxonol dye is dissolved in solvent, and by forming a coating by applying the prepared coating solution onto the surface of the substrate 10. After then, the formed coating is dried to form the resist layer 30. In this case, the thickness of the resist layer 30 is determined in such a manner that an optical density (OD value) is greater than or equal to 1.0 and less than or equal to 1.6 with respect to light having the wavelength of 580 nm. The optical density is determined in such a manner, because if the OD value is too low or too high, the shapes of ring-shaped patterns that are finally formed are not uniform. Here, the OD value represents, by a logarithm, the degree of absorption of light when the light passes through the resist layer 30.

As the oxonol dye, a dye disclosed, for example, in Japanese Unexamined Patent Publication No. 2006-212790 may be used. One of examples of the desirable structure of oxonol dye is represented by the following general formula (1):

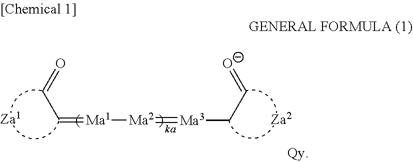

In the general formula (1), each of Za¹ and Za² independently represents a group of atoms forming an acidic nucleus. Further, each of Ma¹, Ma² and Ma³ independently represents a substituted or unsubstituted methine group, and ka represents an integer of from 0 to 3. Plural Ma¹, Ma², which are present when ka is 2 or greater, may be the same, or different. Further, Q represents an ion that neutralizes a charge, and y represents the number of ions necessary to neutralize the charge.

Further, one of examples of desirable structure of oxonol dye is represented by the following general formula (2):

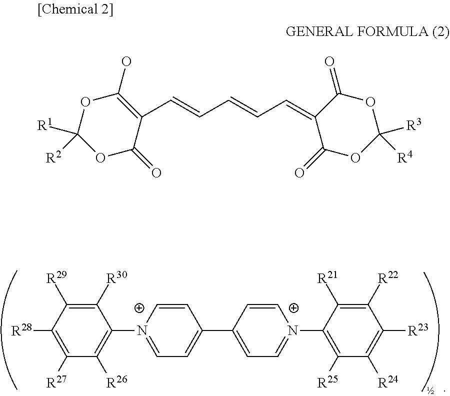

In the general formula (2), each of R¹, R², R³ and R⁴ independently represents a substituted or unsubstituted alkyl group, or a substituted or unsubstituted aryl group, or a substituted or unsubstituted heterocyclic group. Further, each of R²¹, R²², R²³, R²⁴, R²⁵, R²⁶, R²⁷, R²⁸, R²⁹, and R³⁰ independently represents a hydrogen atom, or a substituent.

Alternatively, oxonol-based dyes A and B, which will be described next, may be used as the oxonol dye. As the oxonol dye A, a compound represented by the following general formula (3) is desirable:

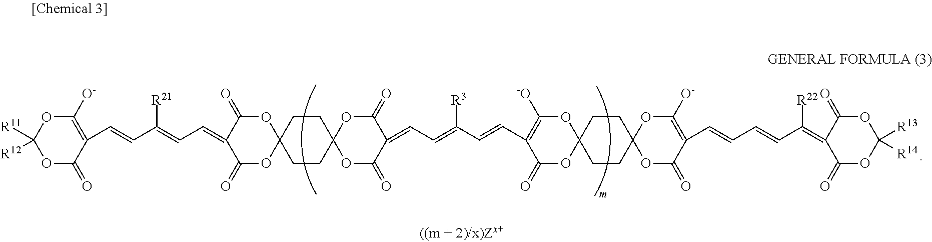

In the general formula (3), each of R¹¹, R¹², R¹³ and R¹⁴ independently represents a hydrogen atom, or a substituted or unsubstituted alkyl group, or a substituted or unsubstituted aryl group, or a substituted or unsubstituted heterocyclic group. Further, R²¹, R²² and R³ represent a hydrogen atom, or a substituted or unsubstituted alkyl group, or a substituted or unsubstituted alkoxy group, or a substituted or unsubstituted aryl group, or a substituted or unsubstituted aryloxy group, or a substituted or unsubstituted heterocyclic group, or a halogen atom, or a carboxy group, or a substituted or unsubstituted alkoxycarbonyl group, or a cyano group, or a substituted or unsubstituted acyl group, or a substituted or unsubstituted carbamoyl group, or an amino group, or a substituted amino group, or a sulfo group, or a hydroxy group, or a nitro group, or a substituted or unsubstituted alkylsulfonylamino group, or a substituted or unsubstituted arylsulfonylamino group, or a substituted or unsubstituted carbamoylamino group, or a substituted or unsubstituted alkylsulfonyl group, or a substituted or unsubstituted arylsulfonyl group, or a substituted or unsubstituted alkylsulfinyl group, or a substituted or unsubstituted arylsulfinyl group, or a substituted or unsubstituted sulfamoyl group, and m represents an integer greater than or equal to 0. Plural R3, which are present when m is 2 or greater, may be the same, or different. Further, Z^{x+} represents a cation, and x is an integer greater than or equal to 1.

As oxonol dye B, a compound represented by the following general formula (4) is desirable:

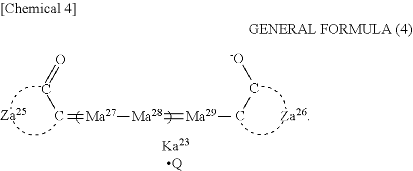

In the general formula (4), each of Za²⁵ and Za²⁶ independently represents a group of atoms forming an acidic nucleus. Further, each of Ma²⁷, Ma²⁸ and Ma²⁹ independently represents a substituted or unsubstituted methine group, and Ka²³ represents an integer of from 0 to 3. Further, Q represents a cation that neutralizes a charge.

As solvent for the coating solution, esters, such as butyl acetate, ethyl lactate and cellosolve acetate; ketones, such as methyl ethyl ketone, cyclohexanone and methyl isobutylketone; chlorinated hydrocarbons, such as dichloromethane, 1,2-dichloroethane and chloroform; amides, such as dimethylformamide; hydrocarbons, such as cyclohexane; ethers, such as tetrahydrofuran, ethyl ether and dioxane; alcohols, such as ethanol, n-propanol, isopropanol, n-butanol and diacetone alcohol; fluorine-based solvents, such as 2,2,3,3-tetrafluoropropanol; and glycol ethers, such as ethylene glycol monomethyl ether, ethylene glycol monoethyl ether and propylene glycolmonomethyl ether, may be used.

The coating method is, for example, a spray method, a spin coating method, a dip method, a roll coating method, a blade coating method, a doctor roll method, a screen printing method, or the like.

### [Protective Layer Formation Step]

Next, as illustrated in Section c of FIG. 1, a protective layer 40 is formed on the resist layer 30. The protective layer 40 is formed by applying a coating of ZnO—Ga2O3, TaOx, NbOx, SiN or the like by using a coating method, such as sputtering, vapor deposition, and application. The coating method is, for example, a sputter method, or the like. In this case, the protective layer 40 is formed in such a manner that the thickness of the protective layer 40 is less than or equal to 10 nm. If the protective layer 40 is too thick, ring-shaped patterns are not formable. Further, it is desirable that the protective layer is transparent with respect to the wavelength of laser to be used. Further, the power of laser in laser beam scan, which will be described later, may be adjusted based on the refractive index of the protective layer.

### [Laser Beam Scan Step]

Next, as illustrated in Section d of FIG. 1, the resist layer 30 is scanned with a laser beam condensed by a lens in an optical system 50. The entire area of the disk-shaped substrate 10 on which the resist layer 30 and the protective layer 40 are deposited is scanned with a laser beam, for example, by moving the optical system 50 in the direction of the radius of the substrate 10 while the substrate 10 is rotated.

In this case, the behavior of either one or both of the substrate 10 and the optical system 50 is controlled so that the relative scan speed of the laser beam that scans the resist layer 30 is higher than or equal to 3 m/s and less than or equal to 10 m/s, because ring-shaped patterns are not formable if the scan speed is too low or too high. Further, it is more desirable that the scan speed is controlled in the range of from 3.8 m/s to 9.2 m/s.

Power Y of the laser beam is set so as to satisfy the condition of the following formula (1) with respect to scan speed X of the laser beam when the OD value of the resist layer 30 is 1.23 and no protective layer is provided. The power Y is set in such a manner, because ring-shaped patterns are not formable if the power is too low or too high:

$$\begin{matrix}[ Formula 1 ] & \\ \{ \begin{matrix}Y > - 0.0331 {X}^{2} + 1.3475 X + 2.1081 \\ Y < - 0.0552 {X}^{2} + 2.2458 X + 3.5136 .\end{matrix} & ( 1 )\end{matrix}$$

It is more desirable to set the power Y of the laser beam so as to further satisfy the condition of the following formula (2). It is still more desirable to set the power Y of the laser beam so as to further satisfy the condition of the following formula (3). When the power Y of the laser beam satisfies the condition of the formula (2), it is possible to more stably form high-resolution ring-shaped patterns. When the power Y of the laser beam satisfies the condition of the formula (3), it is possible to form high-resolution ring-shaped patterns in most excellent shape:

$$\begin{matrix}[ Formula 1 ] & \\ \{ \begin{matrix}Y > - 0.0353 {X}^{2} + 1.4373 X + 2.2487 \\ Y < - 0.053 {X}^{2} + 2.156 X + 3.373 ;\end{matrix} \\ and & ( 1 ) \\ [ Formula 3 ] & \\ Y = - 0.0442 {X}^{2} + 1.7966 X + 2.8109 . & ( 3 )\end{matrix}$$

Further, it is desirable to set the power Y of the laser beam so as to satisfy the condition of the following formula (4) with respect to OD value T of the resist layer 30 when no protective layer is provided and the scan speed of the laser beam is 9.2 m/s:

[Formula 4]

Y=12.303T²−25.236T+28.026 (4).

Further, it is desirable to set the power Y of the laser beam so as to satisfy the condition of the following formula (5) with respect to refractive index R of the protective layer 40 when the OD value of the resist layer 30 is 1.23, and the thickness of the protective layer is 5 nm, and the scan speed of the laser beam is 9.2 m/s:

[Formula 5]

Y=18.284R²−68.221R+77.53 (5).

### [Development Step]

Finally, as illustrated in Section e of FIG. 1, the resist layer 30 that has been scanned with the laser beam is developed with a developer containing alcohol as a main component thereof. Then, ring-shaped patterns 30a are formed in a portion scanned with the laser beam.

Here, examples of alcohol are methanol (methyl alcohol), ethanol (ethyl alcohol), and the like. A development method is, for example, a method in which the substrate 10 on which the resist layer 30 was deposited, and which has been scanned with the laser beam, is immersed for a predetermined period in a developer stored in a development bath. When the developer is methanol, it is desirable that the immersion time is in the range of from 5 to 20 minutes. If the immersion time is too short, ring-shaped patterns are not formable. If the immersion time is too long, ring-shaped patterns are dissolved.

The following table 1 shows a result of evaluation of patterns formed by using the pattern formation method of the present invention. A resist layer 30 the OD value of which is 1.23 was formed by applying a coating solution on a substrate 10 made of silicon (Si) by spin coating, and the coating solution having been obtained by dissolving 2.00 g of “oxonol dye A” represented by the following chemical formula in 100 ml of 2,2,3,3-tetrafluoropropanol, and no protective layer 40 was formed. The patterns were formed by changing the power of the laser beam to 6.5, 7.0, 7.5, . . . , 20 (mW) while the scan speed of the laser beam is fixed at each of 3.8, 9.2, 15.4 (m/s).

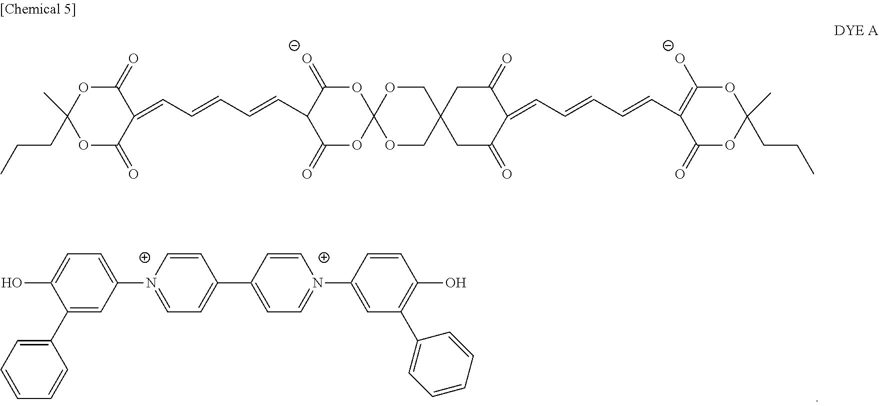

TABLE 1

| | | POWER [mW] | | | | | | | | | | | | | |
|---|---|---|---|---|---|---|---|---|---|---|---|---|---|---|---|
| | | 6.5 | 7 | 7.5 | 8 | 8.5 | 9 | 9.5 | 10 | 10.5 | 11 | 11.5 | 12 | 12.5 | 13 |
| LINEAR VELOCITY | 3.8 | x(a) | Δ | ∘ | ∘ | ∘ | ∘ | ∘ | ∘ | ∘ | Δ | x(b) | x(b) | x(b) | x(b) |
| [m/s] | 9.2 | x(a) | x(a) | x(a) | x(a) | x(a) | x(a) | x(a) | x(a) | x(a) | x(a) | x(a) | Δ | ∘ | ∘ |
| | 15.4 | x(a) | x(a) | x(a) | x(a) | x(a) | x(a) | x(a) | x(a) | x(a) | x(a) | x(a) | x(a) | x(a) | x(a) |
| | | POWER [mW] | | | | | | | | | | | | | |
| | | 13.5 | 14 | 14.5 | 15 | 15.5 | 16 | 16.5 | 17 | 17.5 | 18 | 18.5 | 19 | 19.5 | 20 |
| LINEAR VELOCITY | 3.8 | x(b) | x(b) | x(b) | x(b) | x(b) | x(b) | x(b) | x(b) | x(b) | x(b) | x(b) | x(b) | x(b) | x(b) |
| [m/s] | 9.2 | ∘ | ∘ | ∘ | ∘ | ∘ | ∘ | ∘ | ∘ | ∘ | ∘ | ∘ | Δ | x(b) | x(b) |
| | 15.4 | x(a) | x(a) | x(a) | x(a) | x(c) | x(c) | x(c) | x(c) | x(c) | x(c) | x(c) | x(c) | x(c) | x(c) |

In Table 1, patterns are evaluated in the following manner. When a ring-shaped pattern smaller than or equal to the spot diameter of the optical system 50 is formed in the resist layer portion scanned with the laser beam, the evaluation is ∘. Even if ring-shaped patterns are formed, if the shapes of the patterns are not uniform, the evaluation is Δ. When no ring-shaped pattern is formed, the evaluation is ×(a). When a ring-shaped pattern larger than the spot diameter of the optical system 50 is formed, the evaluation is ×(b). When a hole (depression) is formed in the entire area of the resist layer portion scanned with the laser beam without development using methanol, the evaluation is ×(c).

As table I shows, when the OD value of the resist layer 30 was 1.23, and scan speed X of the laser beam was higher than or equal to 3.8 m/s and lower than or equal to 9.2 m/s, and power Y of the laser beam satisfied the condition of the aforementioned formula (1), it was possible to form a ring-shaped pattern smaller than or equal to the spot diameter of the optical system 50.

In the aforementioned embodiments, a case in which the resist layer 30 is made of oxonol dye was described. However, even if the resist layer 30 is made of a material other than the oxonol dye, it is considered that there is a possibility that negative-type processing is performable if the pattern formation condition, such as the OD value of the resist layer 30 and the scan condition of the laser beam, is appropriately set. Here, examples of the other material are methine dye (cyanine dye, hemicyanine dye, styryl dye, oxonol dye, merocyanine dye, and the like), macrocyclic dye (phthalocyanine dye, naphthalocyanine dye, porphyrin dye, and the like), azo dye (including azo metal chelate dye), arylidene dye, complex dye, coumarin dye, azole derivative, triazine derivative, 1-aminobutadiene derivative, cinnamic acid derivative, quinophthalone dye, and the like.

Next, examples in which the effects of the present invention have been recognized, and comparative examples will be described.

### EXAMPLE 1

### Formation of Resist Layer

A resist layer 30 was formed by applying a coating solution on a substrate 10 made of silicon (Si) by spin coating, and the coating solution having been obtained by dissolving 2.00 g of the aforementioned “oxonol dye A” in 100 ml of 2,2,3,3-tetrafluoropropanol. At this time, the resist layer 30 was formed in such a manner that the optical density (OD value) with respect to light having the wavelength of 580 nm is 1.20. Here, the refractive index of the resist layer 30 is 2.2.

### Formation of Protective Layer

A protective layer 40 having the layer thickness of 5.6 nm was formed by sputtering ZnO—Ga2O3 (Target Composition ZnO:Ga2O3 =30 wt %:70 wt %) on the resist layer 30. Here, the refractive index of the protective layer 40 is 1.8.

### Laser Beam Scan

The substrate 10 on which the resist layer 30 and the protective layer 40 had been formed was scanned with a laser beam by using a laser exposure apparatus (laser wavelength A: 660 nm, numerical aperture of object lens NA: 0.60, and spot diameter of laser beam D: 0.66 um (=0.6 λ/NA)) under the following conditions:

| | |
|---|---|
| Scan Speed | 9.2 m/s; |
| Power | 15.6 mW; and |
| Laser Pulse | 10.43 MHz (Duty ratio 26%). |

### Development

The substrate 10 on which the resist layer 30 had been deposited, and which had been scanned with the laser beam, was immersed in methanol for 10 minutes.

### Evaluation

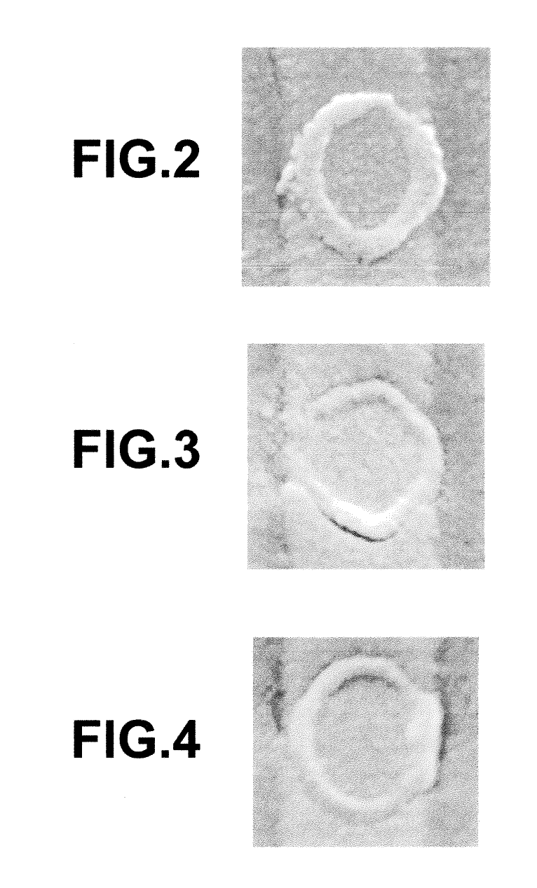

The surface of the substrate 10 after development was observed by a scan-type electronic microscope (SEM). In consequence, formation of a ring-shaped pattern 30a, as illustrated in FIG. 2, was recognized in a portion that had been scanned with the laser beam. The width of the ring-shaped pattern 30a in the direction of laser scan was 0.51 um, and the width of the ring-shaped pattern 30a in a direction orthogonal to the direction of the laser scan was 0.46 um, and the line width of the ring-shaped pattern 30a was 0.08 um.

### EXAMPLE 2

Except for forming a coating having the layer thickness of 2.8 nm, as the protective layer 40, by sputtering TaOx (refractive index: 2.0), and setting the power of a laser beam during scan to 18 mW, processing and evaluation were performed under the same condition as Example 1. In consequence, formation of a ring-shaped pattern 30a, as illustrated in FIG. 3, was recognized in a portion that had been scanned with the laser beam. The width of the ring-shaped pattern 30a in the direction of laser scan was 0.50 um, and the width of the ring-shaped pattern 30a in a direction orthogonal to the direction of the laser scan was 0.46 um, and the line width of the ring-shaped pattern 30a was 0.06 um.

### EXAMPLE 3

Except for forming a coating having the layer thickness of 10.0 nm, as the protective layer 40, by sputtering NbOx (refractive index: 2.1), and setting the power of a laser beam during scan to 20.7 mW, processing and evaluation were performed under the same condition as Example 1. In consequence, formation of a ring-shaped pattern 30a, as illustrated in FIG. 4, was recognized in a portion that had been scanned with the laser beam. The width of the ring-shaped pattern 30a in the direction of laser scan was 0.51 um, and the width of the ring-shaped pattern 30a in a direction orthogonal to the direction of the laser scan was 0.46 um, and the line width of the ring-shaped pattern 30a was 0.05 um.

### EXAMPLE 4

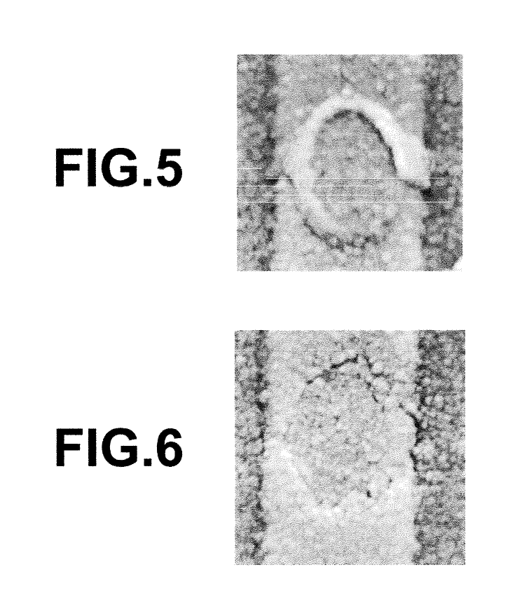

Except for not forming the protective layer 40 (the protective layer formation step was omitted), and for setting the power of a laser beam during scan to 17.6 mW, processing and evaluation were performed under the same condition as Example 1. In consequence, formation of a ring-shaped pattern 30a, as illustrated in FIG. 5, was recognized in a portion that had been scanned with the laser beam. The width of the ring-shaped pattern 30a in the direction of laser scan was 0.46 um, and the width of the ring-shaped pattern 30a in a direction orthogonal to the direction of the laser scan was 0.38 um, and the line width of the ring-shaped pattern 30a was 0.05 um.

### EXAMPLE 5

Except for forming the resist layer 30 in such a manner that the OD value is 1.10, processing and evaluation were performed under the same condition as Example 4. In consequence, formation of a ring-shaped pattern 30a was recognized in a portion that had been scanned with the laser beam. The width of the ring-shaped pattern 30a in the direction of laser scan was 0.45 um, and the width of the ring-shaped pattern 30a in a direction orthogonal to the direction of the laser scan was 0.39 um, and the line width of the ring-shaped pattern 30a was 0.06 um.

### EXAMPLE 6

Except for forming the resist layer 30 in such a manner that the OD value is 1.40, processing and evaluation were performed under the same condition as Example 4. In consequence, formation of a ring-shaped pattern 30a was recognized in a portion that had been scanned with the laser beam. The width of the ring-shaped pattern 30a in the direction of laser scan was 0.47 um, and the width of the ring-shaped pattern 30a in a direction orthogonal to the direction of the laser scan was 0.41 um, and the line width of the ring-shaped pattern 30a was 0.07 um.

### EXAMPLE 7

Except for forming the resist layer 30 in such a manner that the OD value is 1.50, processing and evaluation were performed under the same condition as Example 4. In consequence, formation of a ring-shaped pattern 30a was recognized in a portion that had been scanned with the laser beam. The width of the ring-shaped pattern 30a in the direction of laser scan was 0.46 um, and the width of the ring-shaped pattern 30a in a direction orthogonal to the direction of the laser scan was 0.40 um, and the line width of the ring-shaped pattern 30a was 0.06 um.

### COMPARATIVE EXAMPLE 1

Except for forming the protective layer 40 having the layer thickness of 16.7 run, and setting the power of a laser beam during scan to 16.3 mW, processing and evaluation were performed under the same condition as Example 1. As a result, no ring-shaped pattern was observed in the portion scanned with the laser beam, as illustrated in FIG. 6.

### COMPARATIVE EXAMPLE 2

Except for forming the protective layer 40 having the layer thickness of 33.0 nm, and setting the power of a laser beam during scan to 15.8 mW, processing and evaluation were performed under the same condition as Example 1. As a result, no ring-shaped pattern was observed in the portion scanned with the laser beam.

### COMPARATIVE EXAMPLE 3

Except for forming a coating having the layer thickness of 48 nm, as the protective layer 40, by sputtering SiN (refractive index: 1.6), and setting the power of a laser beam during scan to 19.6 mW, processing and evaluation were performed under the same condition as Example 1. As a result, no ring-shaped pattern was observed in the portion scanned with the laser beam.

### COMPARATIVE EXAMPLE 4

Except for adopting the following condition in laser beam scan, processing and evaluation were performed under the same condition as Example 1:

| | |
|---|---|
| Scan Speed | 15.4 m/s; |
| Power | 18.7 mW; and |
| Laser Pulse | 17.47 MHz (Duty Ratio 33%). |

As a result, no ring-shaped pattern was observed in the portion scanned with the laser beam.

The inventor of the present invention has found, based on the evaluation results of the examples and comparative examples described so far, that a ring-shaped pattern 30a of the order of several hundreds nm or less is formable by forming, on a substrate 10, a resist layer 30 made of oxonol-based dye, and the OD value of which is greater than or equal to 1.0 and less than or equal to 1.6 with respect to light having the wavelength of 580 nm, and by scanning the formed resist layer 30 with a laser beam at a scan speed of higher than or equal to 3 m/s and lower than or equal to 10 m/s, and by developing the resist layer 30 scanned with the laser beam using a developer containing alcohol as a main component. The reason why the ring-shaped pattern is formable when the aforementioned condition is satisfied is not clear. However, the ring-shaped pattern 30a of the order of several hundreds nm or less was able to be actually formed on the surface of the substrate 10 by satisfying the aforementioned condition at least in the range in which evaluation was performed in the examples.

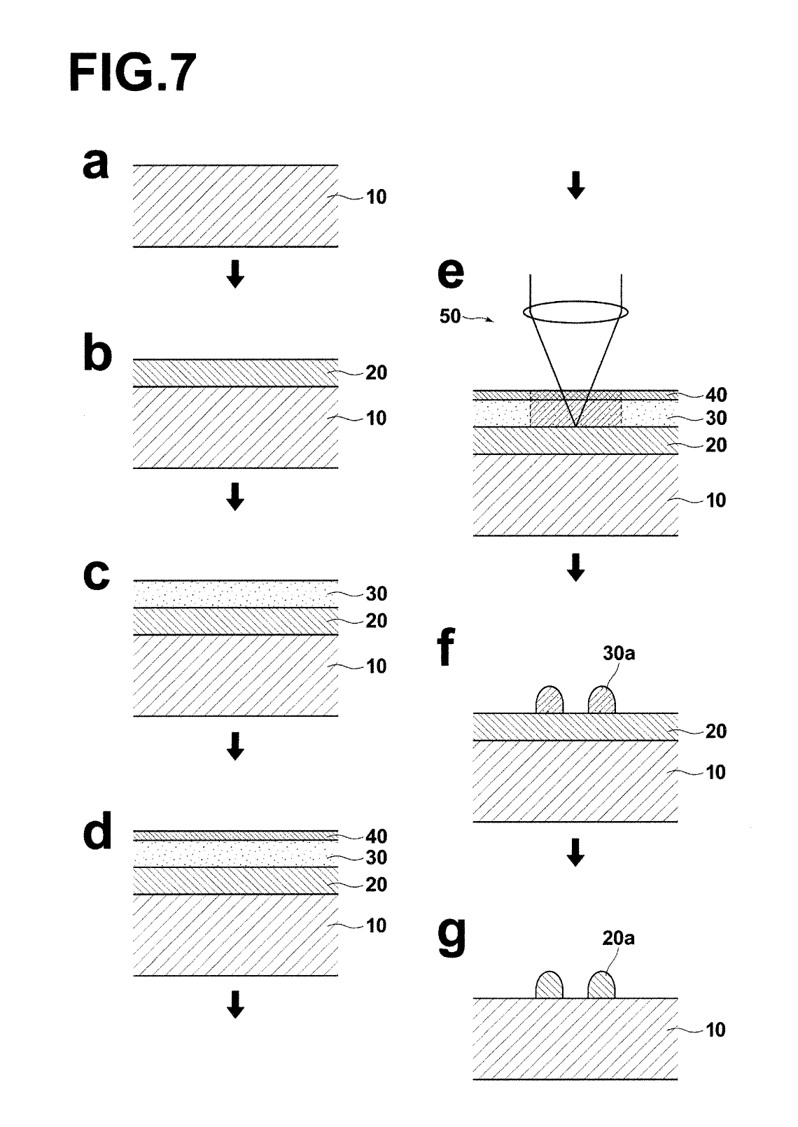

Next, with reference to FIG. 7, embodiments of the metal structure formation method of the present invention will be described. The metal structure formation method of the present invention is a metal structure formation method for forming a ring-shaped metal structure. The metal structure formation method differs from the aforementioned pattern formation method in that a metal layer formation step for forming a metal layer 20 on a substrate 10 is provided before the resist layer formation step, and that an etching step for etching the metal layer 20 using the formed ring-shaped pattern as a mask is provided after the development step. Next, different points from the pattern formation method will be mainly described. The same signs will be assigned to the same components as those of the pattern formation method, and the descriptions of the same components will be omitted.

First, in the metal layer formation step, the metal layer 20 is formed on the substrate 10, as illustrated in Sections a and b of FIG. 7. The metal layer 20 is formed by forming a coating of a material, such as Ag, Au, and Cu, by using a coating method, such as sputtering, vapor deposition, and application. After the metal layer formation step, the aforementioned resist layer formation step, protective layer formation step, laser beam scan step, and development step are sequentially performed, as illustrated in Sections c through f of FIG. 7. Then, the ring-shaped resist pattern is formed in the resist portion on the metal layer 20 that has been irradiated with the laser beam.

Next, following the development step, the etching step is performed by etching the metal layer 20 using the formed ring-shaped resist pattern as a mask, as illustrated in Section g of FIG. 7. Accordingly, the ring-shaped metal structure 20a is formed. Here, the amount of etching is determined based on the thickness of the metal layer 20 so that the substrate 10 is exposed in all of holes of the resist pattern formed on the metal layer 20.

Next, an example in which the effect of the present invention has been recognized will be described.

### EXAMPLE

Except for forming the metal layer 20 of Ag having the layer thickness of 20 nm on the substrate 10 by sputtering Ag before formation of the resist layer 30, and etching the metal layer 20 by Ar ion milling by using the formed ring-shaped pattern 30a as a mask after development, processing and evaluation were performed under the same condition as Example 1. In consequence, formation of a metal ring made of Ag was recognized. The width of the metal ring in the direction of laser scan was 0.53 um, and the width of the metal ring in a direction orthogonal to the direction of the laser scan was 0.48 um, and the line width of the metal ring was 0.09 um.

What is claimed is:

1. A pattern formation method for forming a ring-shaped pattern by thermal lithography, the method comprising the steps of:
forming, on a substrate, a resist layer made of oxonol-based dye, and the OD value of which is greater than or equal to 1.0 and less than or equal to 1.6 with respect to light having the wavelength of 580 nm;
scanning the formed resist layer with a laser beam at a scan speed of higher than or equal to 3 m/s and lower than or equal to 10 m/s; and
developing the resist layer scanned with the laser beam using a developer containing alcohol as a main component.

2. The pattern formation method, as defined in claim 1, the method further comprising the steps of:
forming a protective layer the thickness of which is less than or equal to 10 nm on the formed resist layer; and
scanning the resist layer on which the protective layer has been formed with the laser beam.

3. The pattern formation method, as defined in claim 1, wherein the scan speed is higher than or equal to 3.8 m/s and lower than or equal to 9.2 m/s.

4. The pattern formation method, as defined in claim 1, wherein the alcohol is methanol or ethanol.

5. The pattern formation method, as defined in claim 2, wherein the scan speed is higher than or equal to 3.8 m/s and lower than or equal to 9.2 m/s.

6. The pattern formation method, as defined in claim 2, wherein the alcohol is methanol or ethanol.

7. A metal structure formation method for forming a ring-shaped metal structure, the method comprising the steps of:
forming a metal layer on a substrate;
forming, on the formed metal layer, a resist layer made of oxonol-based dye, and the OD value of which is greater than or equal to 1.0 and less than or equal to 1.6 with respect to light having the wavelength of 580 nm;
scanning the formed resist layer with a laser beam at a scan speed of higher than or equal to 3 m/s and lower than or equal to 10 m/s;
forming a ring-shaped pattern on the metal layer by developing the resist layer scanned with the laser beam using a developer containing alcohol as a main component; and
etching the metal layer by using the formed ring-shaped pattern as a mask.
